(19) United States
(12) Patent Application Publication
(10) Pub. No.: US 2023/0290706 A1
(43) Pub. Date: Sep. 14, 2023

(54) VAPOR CHAMBER INTEGRATED HEAT SPREADER (IHS) WITH LIQUID RESERVOIR

(71) Applicant: Intel Corporation, Santa Clara, CA (US)

(72) Inventors: Gaurav Patankar, Chandler, AZ (US); Shankar Devasenathipathy, Tempe, AZ (US); Krishna Vasanth Valavala, Chandler, AZ (US)

(73) Assignee: Intel Corporation, Santa Clara, CA (US)

(21) Appl. No.: 17/693,003

(22) Filed: Mar. 11, 2022

(51) Int. Cl. H01L 23/427; H01L 23/367; H01L 23/473

(52) U.S. Cl. CPC H01L 23/427; H01L 23/3672; H01L 23/473

(57) ABSTRACT

A surplus liquid reservoir attached to a vapor chamber integrated heat spreader (IHS) and placed near a heat source on a heterogenous die. The vapor chamber integrated heat spreader (IHS) includes a main heat transfer portion that encloses a vapor channel, a first wick material, and a first working fluid. The surplus liquid reservoir is provided by a reservoir leg mechanically coupled, on a first side, to the main heat transfer portion, the reservoir leg has a reservoir portion with a second working fluid and second wick material that is in contact with the first wick material. The surplus liquid reservoir can either support a PL2 that is higher than a given vapor chamber Qmax for a significantly long time or increase the PL2 value to a significantly higher value.

### BACKGROUND

The distribution of power consumption density across the area of an integrated circuit component having heterogeneous architectures (e.g., a combination of one or more different processor units (such as graphics processing units (GPU), compute-intensive “big core” central processor units (CPU), and low-power “small core” processor units) can vary based on the workload being performed by the respective processor units. The variations in power consumption density introduce thermal management challenges because excessive temperature can reduce lifetime and functionality of the integrated circuit component.

### BRIEF DESCRIPTION OF THE DRAWINGS

FIG. 1A is a simplified cross-sectional view of a heat spreader apparatus with a liquid reservoir, in accordance with any of the embodiments disclosed herein.

FIG. 1B is a simplified three-dimensional view of a reservoir portion of a reservoir leg, in accordance with any of the embodiments disclosed herein.

FIG. 1C is a simplified cross-sectional view of a system including a heat spreader apparatus with a liquid reservoir leg, in accordance with any of the embodiments disclosed herein.

FIGS. 2A-2B are simplified cross-sectional views of additional embodiments of a system including a heat spreader apparatus with a liquid reservoir leg.

FIG. 3 is a top-down view of an integrated circuit component with a heat source surrounded by reservoir legs, in accordance with any of the embodiments disclosed herein.

FIG. 4 is a chart depicting enhanced performance provided by various embodiments disclosed herein.

FIG. 5 is a top view of a wafer and dies that may embody unpackaged integrated circuit components, in accordance with any of the embodiments disclosed herein.

FIG. 6 is a simplified cross-sectional side view showing an implementation of an integrated circuit component on a die, in accordance with various embodiments disclosed herein.

FIG. 7 is a cross-sectional side view of a microelectronic assembly that may include an apparatus or system embodiment disclosed herein.

FIG. 8 is a block diagram of an example electrical device that may include an apparatus, system, or microelectronic assembly, in accordance with any of the embodiments disclosed herein.

### DETAILED DESCRIPTION

The variations in power consumption density across an integrated circuit component introduce technical challenges. In integrated circuit components with heterogeneous architectures (heterogeneous dies), different types of processor units (e.g., graphics processing unit (GPU), high performance central processing units (CPUs), and low-power CPUs) are integrated onto a single heterogenous die. During operation of the heterogenous die, the different processor unit types may be utilized to perform the work of the operation, and the work performed consumes power. Thus, the operational power consumption of a heterogeneous die can result in hotspots (areas of high temperature due to high power consumption levels) in different locations on the heterogeneous die. The hotspots are thermal management challenges because excessive temperature can reduce lifetime and functionality of the integrated circuit component.

The application of vapor chamber integrated heat spreaders (IHS) represents one technical solution to this technical challenge. However, the use of vapor chambers to cool heterogeneous dies can have drawbacks. A vapor chamber has a limit on an amount of power (referred to as a maximum power, Qₘₐₓ) it can cool without failure. This failure mechanism is referred to as dry-out/dry-off. Typically, this maximum power, Qₘₐₓ, is due to a phenomenon called a capillary limit, which is a limit on, or a maximum mass rate of, a liquid the wick can pull back to a hotspot using its capillary forces. The working fluid is generally selected to maximize Qₘₐₓ.

To remove the requisite amount of heat at a hotspot to keep an integrated circuit component operating within its thermal limits, vapor chamber designs are faced with the competing demands of having a wick thick enough to allow enough working fluid to return to hotspot regions to allow for continued heat removal and having a thin vapor chamber to enable a low evaporative resistance. Additive processing approaches may enable the manufacture of thin vapor chambers that have a sufficiently low Reap, but such manufacturing approaches can add cost and thin vapor chambers may not address the need of having a sufficiently thick wick. The difficulty in satisfying these competing demands may cause a reduction in the maximum burst power levels that an integrated circuit component can operate at (such as the PL2 power level for some Intel® processors, described in more detail below) generation over generation, due to increasing power consumption densities.

Embodiments described herein provide a technical solution to these technical problems in the form of a surplus liquid reservoir that can be placed near a hotspot (specifically, next to a heat source that generates the hotspot) of a heterogenous die. The surplus liquid reservoir can be opportunistically sized and placed near the heat sources that generate the hotspots, to improve cooling capability with additional working fluid and vapor. Owing to the fast response times of vapor movement in a vapor chamber and the proximity of the vapor to the heat source, provided embodiments are well suited for burst (turbo) power scenarios.

Accordingly, embodiments provide a technically improved vapor chamber IHS. The addition of the surplus liquid, via the liquid reservoir, is a technical improvement to the vapor chamber IHS, as it increases the volume of working fluid that is available to the liquid channel IHS in the proximity of a heat source, thereby delaying or averting dryout/dry-off during high power consumption and increasing the thermal performance of the vapor chamber IHS. The embodiments described herein can have the further advantage of enabling or continuing the use of thin vapor chambers. Thinner vapor chambers may enable thinner computing system designs that have a more aesthetically pleasing industrial design.

In the following description, for purposes of explanation, numerous specific details are set forth to provide a thorough understanding thereof. It may be evident, however, that the novel embodiments can be practiced without every one of these specific details. In other instances, well-known circuits, structures, and techniques may not have been shown in detail, to avoid obscuring an understanding of this description. Phrases such as “an embodiment,” “various embodiments,” “some embodiments,” and the like may include features, structures, or characteristics, but not every embodiment necessarily includes every feature, structure, or characteristic. The intention is to cover all modifications, equivalents, and alternatives within the scope of the claims.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

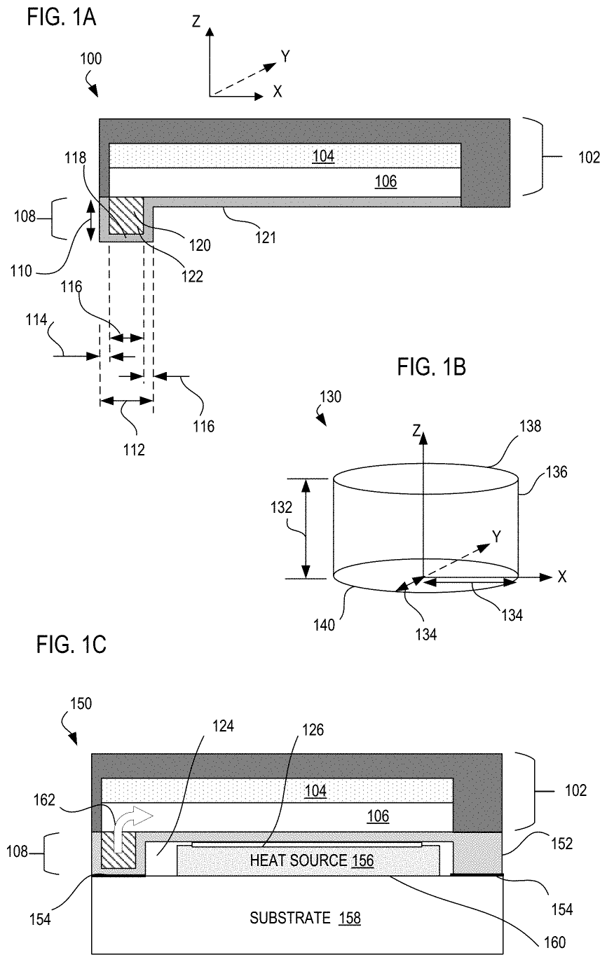

As used herein, the phrase “located on,” in the context of a first layer or first component located on a second layer or second component, refers to either the first layer or component being directly physically attached to the second layer or component (no layers or components between the first and second layers or components), or the first layer or component being physically attached to the second layer or component via one or more intervening layers or components. For example, with reference to FIG. 1A, the heat transfer portion 102 is located on the reservoir leg 108 (perhaps with an intervening adhesive layer).

As used herein, the terms “processor unit”, “processing unit” or “processor” may refer to any device or portion of a device that processes electronic data from registers and/or memory to transform that electronic data into other electronic data that may be stored in registers and/or memory. A processor unit may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

As used herein, the term “electronic component” can refer a battery, or a passive electronic component (e.g., a resistor, an inductor, and a capacitor).

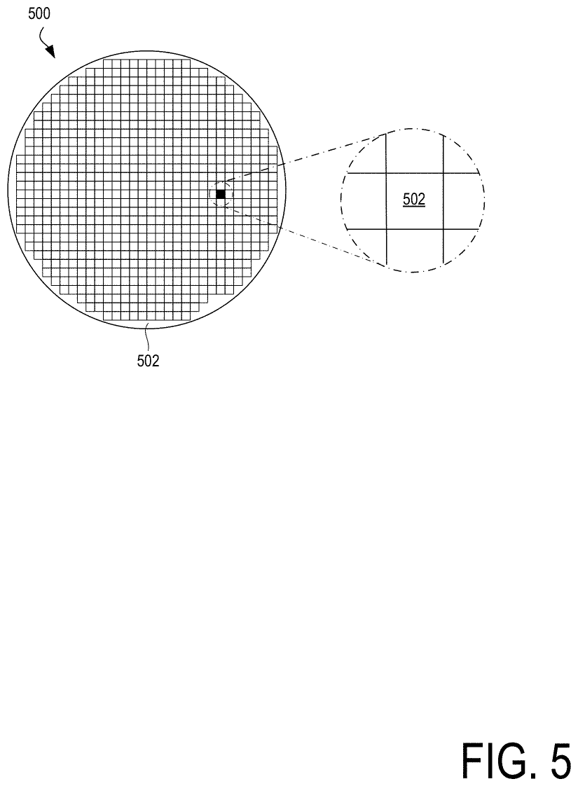

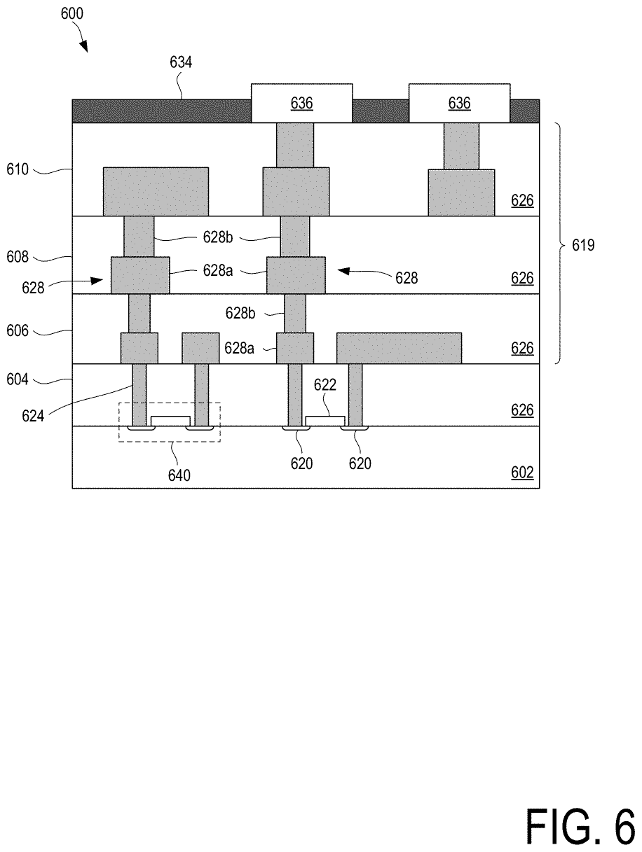

An “integrated circuit component,” as used herein, can comprise at least one processor unit or at least one electronic component, or a combination of processor units and electronic components. Non-limiting examples of an integrated circuit component include a single monolithic integrated circuit die (shortened herein to “integrated circuit die” and “die” and described in more detail in connection with FIGS. 5-6), embodiments of which may have solder bumps attached to contacts on the die, to allow the die to be directly attached to a package substrate or printed circuit board.

As used herein, the phrase “thermally coupled” refers to components that are coupled to facilitate the transfer of heat between them. A thermal interface material (TIM) can be any suitable material to achieve thermal coupling, such as, a silver thermal compound, thermal grease, phase-change materials, indium foils or graphite sheets.

As used herein, the phrase “mechanically coupled” refers to components that are affixed or physically attached (as may be achieved by any combination of soldering, the use of adhesives, the use of fasteners, or the like) to each other, often, to achieve a resulting structure. In various embodiments, mechanically coupled can include releasably attached configurations, such as, those that require application of a torque exceeding a threshold torque to release them.

As may be appreciated by one with skill in the art, thermally coupled and mechanically coupled are not necessarily mutually exclusive, and a coupling between two components can facilitate more than one purpose.

In various processing units, a steady state power level, or power level one (PL1) of some Intel® processors, is a steady operating power level for a processor unit. In contrast, the aforementioned burst power level, or power level two (PL2) of some Intel® processors, represents a “turbo” mode, which is a power level above the PL1 that the processor unit can operate for a short, predefined, duration of time before needing to scale back to PL1.

Reference is now made to the drawings, which are not necessarily drawn to scale, but can be relied upon for general location and orientation purposes for one or more embodiments. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

In the drawings, similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

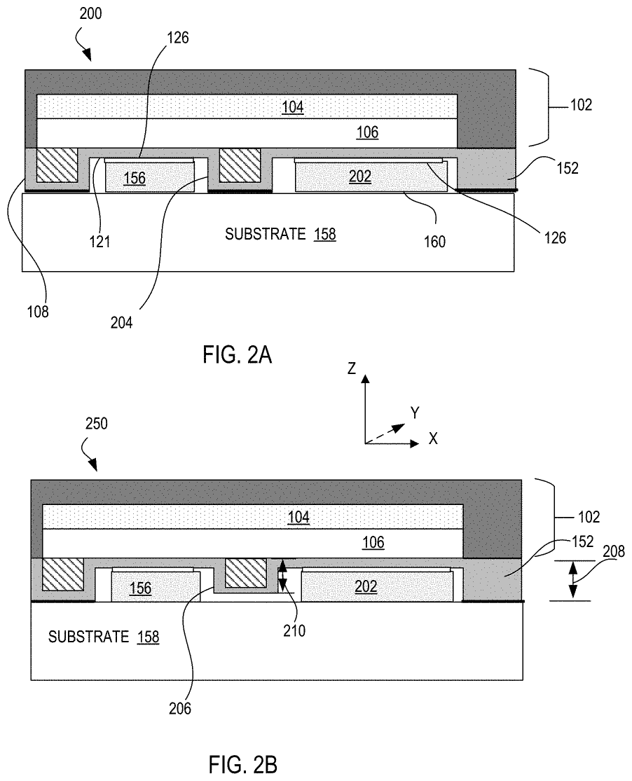

Although the images in FIG. 1A, FIG. 1C, FIG. 2A, and FIG. 2B are depicted in two dimensions, it may be appreciated that in practice, the depicted components have three dimensions. Accordingly, FIG. 1B provides a simplified three-dimensional view of the surplus reservoir leg described herein. FIG. 1A depicts a cross-sectional view of a heat spreader 100 apparatus, in accordance with various embodiments. A main heat transfer portion 102 (shortened herein to heat transfer portion 102) encloses a vapor channel 104, a first wick material 106, and a first working fluid. The first working fluid is in a liquid phase in the first wick material 106. In various embodiments, the heat transfer portion 102 is planar. The heat transfer portion 102 may be formed with a cold plate made of any suitable material for the purpose that is chemically compatible with immersion and working fluids, such as, copper, aluminum, or stainless steel, and in accordance with industry standards.

A reservoir leg 108 is configured to include a liquid reservoir of additional working fluid (referred to as a second working fluid) for use by the heat transfer portion 102. Accordingly, the reservoir leg 108 comprises a volume referred to as a reservoir portion 120, having therein a second wick material 122 that is in contact with the first wick material 106 and further having the second working fluid. The reservoir leg 108 is attached or mechanically coupled, on a first side 138 (e.g., a ceiling side), to bottom side 121, or an integrated circuit component-facing side, of the heat transfer portion 102 and extends generally perpendicular (downward on the page) from the heat transfer portion 102. The first wick material 106 and the second wick material 122 are in contact and thermally coupled. The first wick material 106 and the second wick material 122 may or may not be the same.

The first working fluid and the second working fluid are each a two-phase working fluid, the characteristics of which are further defined herein. The first working fluid and the second working fluid may or may not be the same. When the first working fluid and the second working fluid are not the same, they are miscible. The first working fluid and the second working fluid can comprise water, ammonia, methanol, refrigerants, ethanol, or any of the following fluids or mixture of fluids: sodium dodecyl (SDS), lauryl sulfate (SLS), water and alcohol (the alcohol percentage can range from 10-80%), water and pentane, methanol, ethanol, water and propylene glycol (the propylene glycol percentage can range from 15%-80%), ammonia, ethane, acetone, pentane, refrigerant R-141b (dichlorofluoroethane), refrigerant R-134a, or another fluid or fluid mixture suitable for the purpose described herein.

In operation, the heat transfer portion 102 is filled with a combination of the first working fluid held by the first wick material 106 and vapor (the gas state of the first working fluid) occupying the vapor channel 104. Heat from a heat source 156 causes the first working fluid in the first wick material 106 to vaporize. The vapor travels along the vapor channel 104, away from a hot spot to a cooler location in the heat transfer portion 102, where it condenses back into a liquid state and goes into the first wick material 106. The capillary force in the first wick material 106 pulls the liquid form of the first working fluid back to the area of the heat transfer portion 102 over the heat source 156, thus completing a vapor-liquid flow loop. There is a maximum capillary pressure (liquid flow rate) the first wick material 106 can provide, defined by its material and its porous structure. The power at which the rate of vaporization matches this maximum liquid flow rate is defined as Qmax and the phenomenon is referred to as the capillary limit. In various embodiments, the reservoir portion 120 provides surplus working fluid (in liquid state) pulled by the capillary action 160 into the heat transfer portion 102 at the site of the hot spot, to bolster the performance of the heat transfer portion 102.

The reservoir leg 108 has a leg height 110. In various embodiments, such as, when the reservoir leg 108 is used for structural support, the leg height 110 is predefined, generally, as a function of a target integrated circuit component (see, e.g., FIG. 1C, wherein a target integrated circuit component is heat source 156). The surplus liquid is provided by the reservoir portion 120, which embodies a volume less than a volume of the reservoir leg 108. The volume of the reservoir portion 120 may be characterized by a wall that is continuous and further continuous with, or sealed to, a floor 118 extending in the X direction (and the X-Y plane).

The wall is depicted with outside wall 114 and inside wall 116, which may or may not be equal. In this context, the inside wall 116 is configured to face a cavity 124 and be located next to a heat source 156, and the outside wall is furthest from the heat source 156 in the Figure. As used herein, a component being described as “next to” a second component can be physically touching the second component or not physically touching the second component, yet adjacent to, or proximate to, the second component.

The cavity 124 is created by the integration of one or more reservoir legs 108 and one or more support legs 152 (wherein support legs 152 are characterized as legs not comprising a reservoir) with the heat transfer portion 102.

In various embodiments, the reservoir portion 120 may have a wall thickness of about 10-20% of a width 112 of the reservoir leg 108. The second wick material 122 substantially fills the reservoir portion 120 and may occupy about 60-80% of a volume of the reservoir leg 108.

The first wick material 106 and the second wick material 122 can comprise sintered copper powder, copper fibers (which, in some embodiments, can be woven into forms such as a screen, mesh, or braids), or grooves integrated into a surface of the vapor chamber 104. The first wick material 106 and the second wick material 122 can comprise a pattern or a plurality of patterns. In some embodiments, the first wick material 106 and the second wick material 122 are different from each other. In other embodiments, the first wick material 106 and the second wick material 122 are the same.

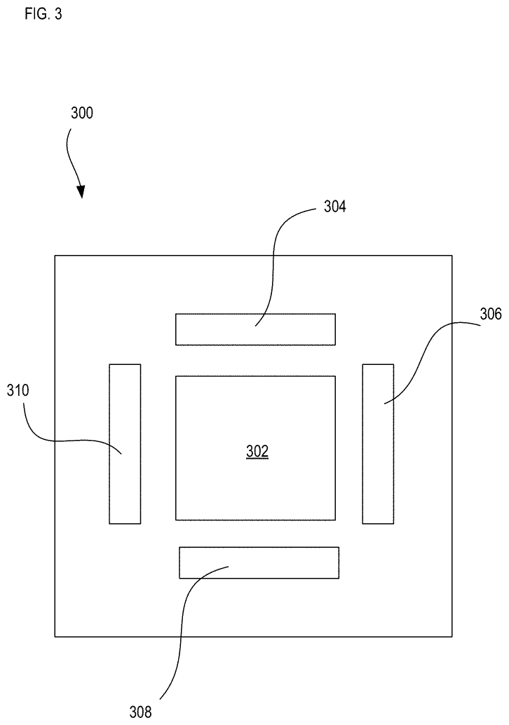

With reference to FIG. 1B, a simplified three-dimensional illustration depicts an embodiment of the volume 130 of the reservoir portion as being cylindrical around an axis in the Z direction, with all radius measurements 134 therefrom being equal. Note that in the two-dimensional images, the reservoir leg is described as having a width, whereas in the three-dimensional image of FIG. 1B, the width translates to a diameter (twice the radius measurement 134, plus added wall thickness). Although this illustration is helpful for introducing features, it may be appreciated that in practice, variations in processing or manufacturing may alter the shape of any given reservoir portion. Additionally, in various embodiments, the volume of the reservoir portion may be rectangular (e.g., see FIG. 3, volumes 306), oval, or any other shape that supports the surplus liquid reservoir functionality described herein.

Although the wall 136 may have a wall thickness that is not necessarily uniform as one circumnavigates the wall, the wall 136 is continuous or uninterrupted radially, around its axis, substantially enclosing the volume 130 of the reservoir portion in the Z direction. The wall thickness may be subject to a minimum thickness that is a function of a first requirement to prevent leakage of the second working fluid. The minimum thickness may also be a function of a second requirement to support at least a portion of a load applied by the main heat transfer portion 102. The reservoir portion 136 is characterized by a wall height 132 that is the leg height 110 minus a floor thickness. The floor thickness may be in the range of 100 to 200 microns. The floor 118 may have a floor thickness substantially equal to the thickness of the wall. As used herein, “substantially” equal to means plus or minus two percent from the thickness of the wall.

FIG. 1C an apparatus 150 depicts the heat spreader 100 apparatus and a heat source 156. As used herein, a heat source may be all, or part of an integrated circuit die or another electronic component. In practice, the heat source 156 may be thermally coupled to the vapor chamber of the heat transfer portion 102. In various embodiments, the thermal coupling is provided by a TIM 126 (thermal interface material) located between a first side, or ceiling side, of the heat source 156 and the bottom 121/floor side of the vapor chamber integrated heat spreader. The heat source 156 may be mechanically coupled on a second side 160 to package substrate 158.

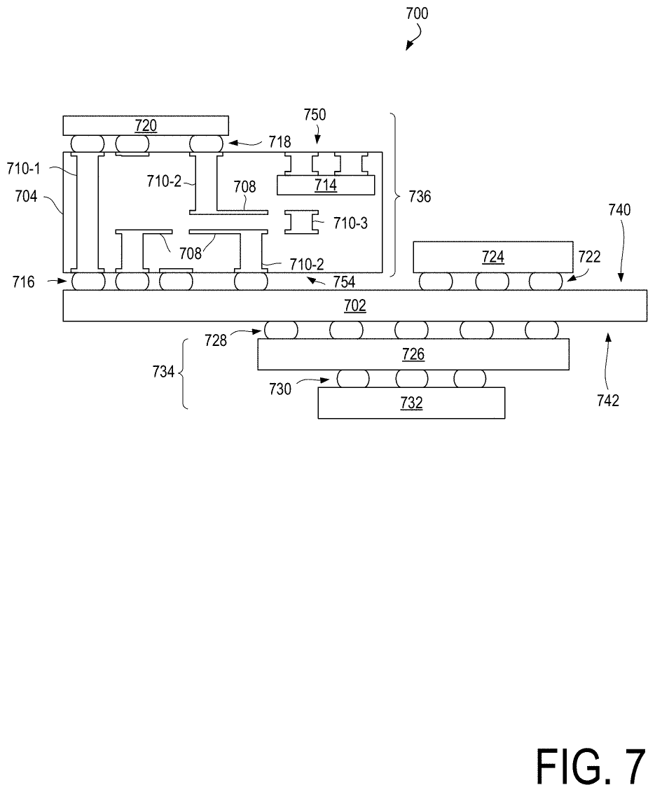

The heat source 156 may be all or part of an integrated circuit component that can comprise a plurality of processor units. The apparatus 150 may further be part of a larger microelectronic assembly (see, e.g., FIG. 7). The heat source 156 can generate a hotspot during its operation, responsive to a steady-state (e.g., PL1) or a turbo power or burst power, PL2, consumption. In various embodiments, the heat spreader 100 is positioned such that the heat transfer portion 102 is planar and positioned over the heat source 156. In various embodiments, the heat spreader 100 serves as a protective shell around the heat source 156 and as a pathway for heat to be exchanged between the heat source 156 and a system cooler.

In the example, the heat source 156 is a target for the reservoir leg 108, so the reservoir leg 108 is located next to the targeted heat source, heat source 156. It is important that a respective reservoir leg 108 be near the heat source 156 that is targeted for the respective reservoir leg, such that working fluid can efficiently flow into an evaporator region of the heat transfer portion 102 during high power transients or burst power by the heat source 156. Although the reservoir leg 108 is depicted as being located next to the heat source 156 and also at a peripheral edge of a die that the apparatus 150 may embody, in other embodiments, the reservoir leg 108 may be internal to an integrated circuit component. In various embodiments, the reservoir leg 108 is a first reservoir leg of multiple reservoir legs 108, the multiple reservoir legs are arranged around the heat source such that they are all located next to the heat source 156. In various embodiments, one or more reservoir legs 108 are substantially perpendicular and extending downward (with the orientation of downward as shown in the illustration) from the heat transfer portion 102.

Whereas FIG. 1C depicts the reservoir leg 108 located at a periphery/edge of an integrated circuit component, with a floor side being coupled to an associated die substrate 158, in other embodiments, one or more reservoir legs can be placed internal to a semiconductor integrated circuit product that includes one or more integrated circuit components behaving as heat sources. FIG. 2A and FIG. 2B illustrate additional embodiments of an apparatus 200 and an apparatus 250, each including a respective heat spreader apparatus thermally coupled to multiple heat sources, the heat spreader apparatus including a reservoir leg located between two adjacent heat sources of the multiple heat sources. As before, the integrated circuit components comprising the multiple heat sources may be thermally coupled at a first side or ceiling side (e.g., via TIM 126) to the bottom side 121 of the heat transfer portion 102 and mechanically coupled to a package substrate 158 on/at a second side 154.

As shown in FIG. 2A and FIG. 2B, in embodiments having multiple heat sources, a first reservoir leg 108 can be located between a first heat source (156) of the multiple heat sources and a peripheral/external edge of the substrate 158, and in addition, a second reservoir leg 204 can be placed in between the first heat source and an adjacent second heat source of the multiple heat sources (e.g., between heat source 156 and heat source 202). In various embodiments, peripherally located reservoir leg 108 is optionally removed, just an internally located reservoir leg 204 is present. In various embodiments, as shown in FIG. 2B, wherein the heat transfer portion 102 is mechanically coupled to a substrate 158 (die substrate is defined in connection with FIG. 6) via at least one support leg 152 having a first height 208, a reservoir leg 206 can have a leg height 210 that is not the same, e.g., smaller than a height 208 of the support leg 152, thereby not extending all the way to the substrate 158, and not contacting the substrate 158. This is depicted in FIG. 2B, reservoir leg 206 may not extend entirely through the cavity and may not be configured to attach to the substrate 158.

In some embodiments, the reservoir portion 120 can be created by modifying an existing stability leg (e.g., stability leg 152) to thereby create a reservoir leg 108 with the reservoir portion 120 having the second wick material 122 and surplus working fluid (the second working fluid), and mechanically coupling the reservoir leg 108 to the main heat spreader portion 102 and/or to a substrate 158 using conventional sealant attach methods. In some embodiments, the reservoir portion 120 can be created by stamping a material into a shape that embodies both the reservoir leg 108 and the reservoir portion 120 and, in various embodiments, the same continuous piece of material may additionally embody a floor side of the heat transfer portion 102.

Each solution illustrated in FIGS. 1A-2B can provide a design and material-specific enhanced cooling capacity over a vapor channel IHS alone, as a function of the selected first and second working fluids and the first and second wick material, as well as the geometry and placement. The enhanced cooling capacity provided by embodiments translates to an increased burst power limit (PL2) for the heat source relying on the solution for heat removal. When this technical solution is implemented with multiple reservoir legs, each configured to target a heat source, each heat source is enabled with an increased burst power limit, the technical improvement provided by this design is further illustrated.

In practice, the surplus liquid reservoir feature disclosed herein is expected to enable the maximum operating power of integrated circuit components (e.g., PL2 levels) to increase by an amount of 10-15% for some integrated circuit component designs. For example, FIG. 3 depicts a top-down view of an apparatus 300 having a die (e.g., CPU) 302 (heat source) with an arrangement of reservoir volumes next to the CPU 302. In the depicted embodiment, the arrangement includes four reservoir volumes 304, 306, 308, and 310 (embodied as reservoir legs, as described herein) placed next to the CPU 302. In the example, the reservoir volumes 304 have dimensions of 30 mm×5 mm×2 mm. The CPU 302 has a PL1 power of approximately 125 W and PL2 power of approximately 241 W. A typical value of Qmax of the vapor chamber IHS of the heat spreader portion 102 used in this design was 200 W, which can support a PL1 of 125 W under steady-state conditions. Analysis of this embodiment predicted that the volume and energy of vaporization that these four liquid reservoir volumes would provide add about 2880 J of surplus energy. Using Equation 1, below,

Operation time=(Energyₛᵤᵣₚₗᵤₛ)/(PL2−Qmax) Eq. 1

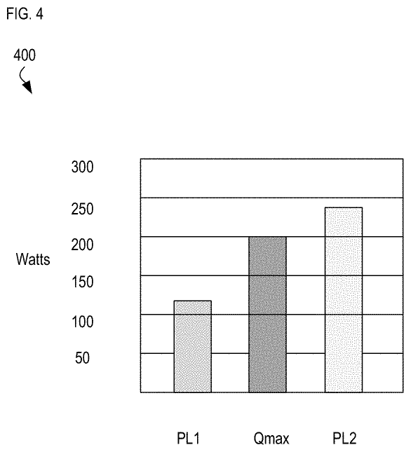

this amount of surplus energy can support the difference between the PL2 and the Qmax (241−200=41 W) for about 70 seconds, which is an objective improvement over existing vapor chamber IHS designs. Thus, as shown in FIG. 4, graph 400, the surplus liquid reservoir design provided herein can support an increased PL2 on the same time scale that a processing unit can be operating at Qmax of 200 W. In practice, this provides that the PL2 turbo scenario can be cooled with a vapor chamber designed for a (lower W) Qmax, thus allowing for thinner vapor chamber integrated heat spreader designs, which can, for example, decrease the overall z-height of a computing system comprising integrated circuit components with the heat spreaders disclosed herein.

Described differently, the heat spreader apparatus 100 includes a primary heat transfer means configured to cool a heat source, the primary heat transfer means being thermally coupled to the heat source, plus a surplus heat transfer means configured to provide surplus liquid to the primary heat transfer means when operating above Qmax.

As those with skill in the art will appreciate, the embodiment depicted in FIG. 3 is non-limiting, and a variety of arrangements of reservoir legs with respect to heat sources can be implemented. In some embodiments, a reservoir volume could be located next to just one or two sides of a heat source (e.g., just 304 and 306, or just 304 and 308), instead of around all four sides. In various embodiments, reservoir volumes can be arranged peripherally to a boundary defined by an outer extent of a grouping of multiple heat sources (e.g., instead of block 302 being a single CPU heat source, the block 302 could represent multiple heat sources within a semiconductor product). Additionally, the reservoir volumes and associated reservoir legs can have different sizes/volumes from each other (e.g., volume 304 not equal to volume 306, etc.), with a reservoir volume being a function of a respective heat source next to which it is placed.

FIG. 5 is a top view of a wafer 500 and dies 502 that may represent the integrated circuit components coupled to the head spreader 100 apparatus disclosed herein (e.g., any of the dies 502 may be a heat source 156 or a heat source 202). The wafer 500 may be composed of semiconductor material and may include one or more dies 502 having integrated circuit structures formed on a surface of the wafer 500. The individual dies 502 may be a repeating unit of a semiconductor integrated circuit product that includes one or more integrated circuit components. After the fabrication of the integrated circuit product is complete, the wafer 500 may undergo a singulation process in which the dies 502 are separated from one another to provide discrete “chips” of the integrated circuit product. The die 502 may be any of the heat sources disclosed herein.

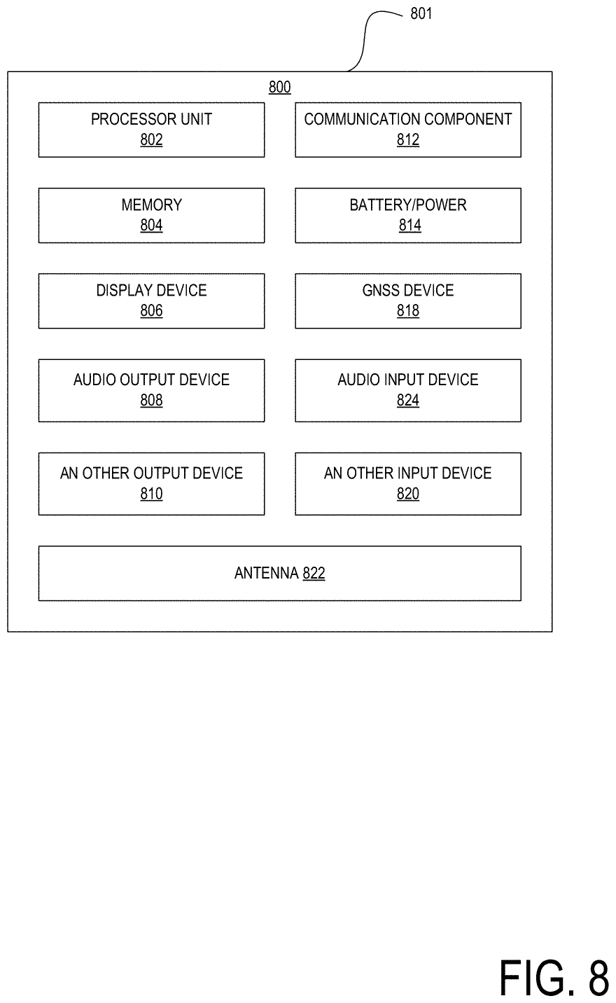

The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies, one or more of which being a heat source 156, are attached to a wafer 500 that include others of the dies, and the wafer 500 is subsequently singulated.

FIG. 6 is a simplified cross-sectional side view showing an implementation of an integrated circuit component 600, such as may be present in a die that is used as the heat source 156 or heat source 202. One or more of the integrated circuit components 600 may be included in one or more dies 502 (FIG. 5). The integrated circuit component 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit component 600 may be used. The die substrate 602 may be part of a singulated die (e.g., the dies 502 of FIG. 5) or a wafer (e.g., the wafer 500 of FIG. 5).

The integrated circuit component 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit component 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit components having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit component 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit component 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit component 600 with another component (e.g., a printed circuit board). The integrated circuit component 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit component 600 (e.g., heat source 156) is a double-sided die, the integrated circuit component 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit component 600 from the conductive contacts 636.

In other embodiments in which the integrated circuit component 600 is a double-sided die, the integrated circuit component 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit component 600 from the conductive contacts 636. In some embodiments, TSVs extending through the substrate can be used for routing power and ground signals from conductive contacts on the opposite side of the integrated circuit component 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit components 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

In various embodiments, the integrated circuit components 600 are assembled into packaged integrated circuit components. A packaged integrated circuit component can comprise one or more of the aforementioned integrated circuit dies mounted on a package substrate. The package substrate facilitates connectivity between the integrated circuit component and a circuit board. Non-limiting examples of the packaging substrate include chip scale packages (CSP), flip chip CSP (FC-CSP), board on chip (BOC), package in package (PiP), system in package (SiP), RF module and LED package. The integrated circuit dies and package substrate are further encapsulated in a casing material, such as a metal, plastic, glass, or ceramic. In one example, a packaged integrated circuit component contains one or more processor units mounted on a package substrate with an exterior surface of the substrate comprising a solder ball grid array (BGA).

In various embodiments, the integrated circuit components 600 are assembled into microelectronic assemblies. Turning now to FIG. 7, a cross-sectional side view of an embodiment of a microelectronic assembly 700 is provided. The microelectronic assembly 700 includes a number of components disposed on a circuit board 702. The microelectronic assembly 700 includes components disposed on a first face 740 of the circuit board 702 and an opposing second face 742 of the circuit board 702; generally, components may be disposed on one or both faces 740 and 742. Any of the integrated circuit components referenced herein as part of the microelectronic assembly 700 may take the form of any suitable apparatus or system embodiments disclosed herein.

In some embodiments, the above-described integrated circuit components 600, packaged integrated circuit components, and/or microelectronic assemblies 700 can be attached to a printed circuit board located in a computing device that comprises a housing that encloses the printed circuit board and the integrated circuit component. In some embodiments, the printed circuit board further has a second integrated circuit component attached thereto.

The circuit board 702 may be a motherboard, system board, mainboard, or the like. In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate.

The microelectronic assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged integrated circuit component that includes one or more integrated circuit dies (e.g., the die 502 of FIG. 5) and/or one or more other suitable components. A packaged integrated circuit component can comprise one or more integrated circuit dies mounted on a package substrate with the integrated circuit dies and package substrate encapsulated in a casing material, such as a metal, plastic, glass, or ceramic. In other embodiments, a packaged integrated circuit component 720 may be a single monolithic integrated circuit die comprising solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The microelectronic assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The microelectronic assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may utilize one or more of the surplus liquid reservoir enhancements to a vapor chamber IHS disclosed herein. For example, any suitable ones of the components of the electrical device 800 may include one or more of the microelectronic assemblies 700, integrated circuit components 720, or integrated circuit dies 502 disclosed herein, and may have a surplus liquid reservoir (as part of the heat spreader apparatus 100) located alongside it, as disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die. In some embodiments, the one or more of these components are enclosed in a housing 801.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

Embodiments of the electrical device 800 may include one or more processor units 802, defined above. The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

As used in this application and the claims, items joined by the term “and/or” can mean any combination of the items. For example, the phrase “A and/or C” can mean A; C; or A and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and sub combinations with one another. The disclosed methods, apparatuses, and systems are not limited to any specific aspect or feature or combination thereof, nor do the disclosed embodiments require that any one or more specific advantages be present, or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.
Example 1 includes an apparatus comprising: a heat transfer portion that encloses a vapor channel, a first wick material, and a first working fluid; and a reservoir leg mechanically coupled to the heat transfer portion on a first side, the reservoir leg comprising a reservoir portion with a second working fluid and second wick material that is in contact with the first wick material.
Example 2 includes the subject matter of Example 1, wherein the first wick material and the second wick material are the same.
Example 3 includes the subject matter of Example 1, wherein the first wick material is different from the second wick material.
Example 4 includes the subject matter of Example 1, wherein the first working fluid and the second working fluid are the same.
Example 5 includes the subject matter of Example 1, wherein the first working fluid is different from the second working fluid, and the first working fluid and the second working fluid are miscible.
Example 6 includes the subject matter of Example 1, wherein the second wick material occupies about 60-80% of a volume of the reservoir leg.
Example 7 includes the subject matter of Example 1, further comprising: a heat source thermally coupled to the heat transfer portion on a first side and mechanically coupled to a die substrate on a second side; and wherein the reservoir leg is located next to the heat source and mechanically coupled on a floor side to the die substrate.
Example 8 includes the subject matter of Example 7, wherein the reservoir leg is a first reservoir leg of multiple reservoir legs, and wherein, the multiple reservoir legs are arranged around the heat source such that they are all located next to the heat source.
Example 9 includes the subject matter of Example 1, further comprising: multiple heat sources thermally coupled to the heat transfer portion on a respective first side and mechanically coupled to a die substrate on a respective second side; and wherein the reservoir leg is a first reservoir leg, located between an edge of the die substrate and a first heat source of the multiple heat sources; and a second reservoir leg located between the first heat source and a second heat source that is adjacent to the first heat source.
Example 10 includes the subject matter of Example 9, wherein the first reservoir leg has a height that is not equal to a height of the second reservoir leg.
Example 11 includes an apparatus comprising: multiple heat sources mechanically coupled to a substrate; a heat spreader apparatus thermally coupled to the multiple heat sources, the heat spreader apparatus including a heat transfer portion that encloses a vapor channel, a first wick material, and a first working fluid; and a reservoir leg mechanically coupled to the heat transfer portion on a first side, the reservoir leg comprising a reservoir portion with a second working fluid and second wick material that is in contact with the first wick material, the reservoir leg being located next to a first heat source of the multiple heat sources.
Example 12 includes the subject matter of Example 11, wherein the reservoir leg is a first reservoir leg of multiple reservoir legs, and wherein, the multiple reservoir legs are arranged around the first heat source such that they are located next to the heat source.
Example 13 includes the subject matter of Example 12, wherein a height of the first reservoir leg of the multiple reservoir legs is not equal to a height of a second reservoir leg of the multiple reservoir legs.
Example 14 includes the subject matter of Example 11, wherein the reservoir leg is a first reservoir leg that is located between an edge of a die and a first heat source of the multiple heat sources, and further comprising a second reservoir leg located between the first heat source and a second heat source that is adjacent to the first heat source.
Example 15 includes the subject matter of Example 14, wherein a height of a first reservoir leg is not equal to a height of a second reservoir leg.
Example 16 includes a system comprising: a printed circuit board; an integrated circuit component mechanically coupled to the printed circuit board; a heat spreader apparatus thermally coupled to the integrated circuit component, the heat spreader apparatus including a heat transfer portion that encloses a vapor channel, a first wick material, and a first working fluid; and a reservoir leg mechanically coupled to the heat transfer portion on a first side, the reservoir leg comprising a reservoir portion with a second working fluid and second wick material that is in contact with the first wick material, the reservoir leg being located next to the integrated circuit component.
Example 17 includes the subject matter of Example 16, further comprising a housing enclosing the printed circuit board and the integrated circuit component.
Example 18 includes the subject matter of Example 16, further comprising a second integrated circuit component attached to the printed circuit board.
Example 19 includes the subject matter of Example 16, wherein the reservoir leg is a first reservoir leg of multiple reservoir legs, and wherein, the multiple reservoir legs are arranged around the integrated circuit component such that they are located next to a heat source in the integrated circuit component.
Example 20 includes the subject matter of Example 19, wherein a height of the first reservoir leg of the multiple reservoir legs is not equal to a height of a second reservoir leg of the multiple reservoir legs.
Example 21 includes the subject matter of Example 16, wherein the integrated circuit component is on a die, the reservoir leg is a first reservoir leg that is located between an edge of the die and a first heat source of the integrated circuit component, and further comprising a second reservoir leg located between the first heat source and a second heat source that is adjacent to the first heat source on the integrated circuit component.
Example 22 provides a heat spreader apparatus, comprising: a primary heat transfer means configured to cool a heat source using a liquid flow rate, the primary heat transfer means being thermally coupled to the heat source; and a surplus heat transfer means configured to provide surplus liquid to the primary heat transfer means when the primary heat transfer means exceeds the liquid flow rate.
Example 23 includes the subject matter of Example 22, wherein: the heat source is thermally coupled to the primary heat transfer means on a first side and mechanically coupled to a die substrate on a second side; and the surplus heat transfer means is located next to the heat source and mechanically coupled on a floor side to the die substrate.
Example 24 includes the subject matter of Example 22, further comprising: multiple heat sources thermally coupled to the primary heat transfer means on a respective first side and mechanically coupled to a die substrate on a respective second side; and wherein the surplus heat transfer means is a first surplus heat transfer means, located between an edge of the die substrate and a first heat source of the multiple heat sources; and a second surplus heat transfer means located between the first heat source and a second heat source that is adjacent to the first heat source.
Example 25 includes the subject matter of Example 22, wherein the first surplus heat transfer means has a height that is not equal to a height of the second surplus heat transfer means.

What is claimed is:

1. An apparatus comprising:
a heat transfer portion that encloses a vapor channel, a first wick material, and a first working fluid; and
a reservoir leg mechanically coupled to the heat transfer portion on a first side, the reservoir leg comprising a reservoir portion with a second working fluid and second wick material that is in contact with the first wick material.

2. The apparatus of claim 1, wherein the first wick material and the second wick material are the same.

3. The apparatus of claim 1, wherein the first wick material is different from the second wick material.

4. The apparatus of claim 1, wherein the first working fluid and the second working fluid are the same.

5. The apparatus of claim 1, wherein the first working fluid is different from the second working fluid, and the first working fluid and the second working fluid are miscible.

6. The apparatus of claim 1, wherein the second wick material occupies about 60-80% of a volume of the reservoir leg.

7. The apparatus of claim 1, further comprising: a heat source thermally coupled to the heat transfer portion on a first side and mechanically coupled to a die substrate on a second side; and wherein the reservoir leg is located next to the heat source and mechanically coupled on a floor side to the die substrate.

8. The apparatus of claim 7, wherein the reservoir leg is a first reservoir leg of multiple reservoir legs, and wherein, the multiple reservoir legs are arranged around the heat source such that they are all located next to the heat source.

9. The apparatus of claim 1, further comprising: multiple heat sources thermally coupled to the heat transfer portion on a respective first side and mechanically coupled to a die substrate on a respective second side; and wherein the reservoir leg is a first reservoir leg, located between an edge of the die substrate and a first heat source of the multiple heat sources; and a second reservoir leg located between the first heat source and a second heat source that is adjacent to the first heat source.

10. The apparatus of claim 9, wherein the first reservoir leg has a height that is not equal to a height of the second reservoir leg.

11. An apparatus comprising:
multiple heat sources mechanically coupled to a substrate; and
a heat spreader apparatus thermally coupled to the multiple heat sources, the heat spreader apparatus including:
a heat transfer portion that encloses a vapor channel, a first wick material, and a first working fluid; and
a reservoir leg mechanically coupled to the heat transfer portion on a first side, the reservoir leg comprising a reservoir portion with a second working fluid and second wick material that is in contact with the first wick material, the reservoir leg being located next to a first heat source of the multiple heat sources.

12. The apparatus of claim 11, wherein the reservoir leg is a first reservoir leg of multiple reservoir legs, and wherein, the multiple reservoir legs are arranged around the first heat source such that they are located next to the heat source.

13. The apparatus of claim 12, wherein a height of the first reservoir leg of the multiple reservoir legs is not equal to a height of a second reservoir leg of the multiple reservoir legs.

14. The apparatus of claim 11, wherein the reservoir leg is a first reservoir leg that is located between an edge of a die and a first heat source of the multiple heat sources, and further comprising a second reservoir leg located between the first heat source and a second heat source that is adjacent to the first heat source.

15. The apparatus of claim 14, wherein a height of a first reservoir leg is not equal to a height of a second reservoir leg.

16. A system comprising:
a printed circuit board;
an integrated circuit component mechanically coupled to the printed circuit board; and
a heat spreader apparatus thermally coupled to the integrated circuit component, the heat spreader apparatus including:
a heat transfer portion that encloses a vapor channel, a first wick material, and a first working fluid; and
a reservoir leg mechanically coupled to the heat transfer portion on a first side, the reservoir leg comprising a reservoir portion with a second working fluid and second wick material that is in contact with the first wick material, the reservoir leg being located next to the integrated circuit component.

17. The system of claim 16, further comprising a housing enclosing the printed circuit board and the integrated circuit component.

18. The system of claim 16, further comprising a second integrated circuit component attached to the printed circuit board.

19. The system of claim 16, wherein the reservoir leg is a first reservoir leg of multiple reservoir legs, and wherein, the multiple reservoir legs are arranged around the integrated circuit component such that they are located next to a heat source in the integrated circuit component.

20. The system of claim 19, wherein a height of the first reservoir leg of the multiple reservoir legs is not equal to a height of a second reservoir leg of the multiple reservoir legs.

21. The system of claim 16, wherein the integrated circuit component is on a die, the reservoir leg is a first reservoir leg that is located between an edge of the die and a first heat source of the integrated circuit component, and further comprising a second reservoir leg located between the first heat source and a second heat source that is adjacent to the first heat source on the integrated circuit component.

22. A heat spreader apparatus, comprising:
a primary heat transfer means configured to cool a heat source using a liquid flow rate, the primary heat transfer means being thermally coupled to the heat source; and
a surplus heat transfer means configured to provide surplus liquid to the primary heat transfer means when the primary heat transfer means exceeds the liquid flow rate.

23. The heat spreader apparatus of claim 22, wherein:
the heat source is thermally coupled to the primary heat transfer means on a first side and mechanically coupled to a die substrate on a second side; and
the surplus heat transfer means is located next to the heat source and mechanically coupled on a floor side to the die substrate.

24. The heat spreader apparatus of claim 22, further comprising:
multiple heat sources thermally coupled to the primary heat transfer means on a respective first side and mechanically coupled to a die substrate on a respective second side;
wherein the surplus heat transfer means is a first surplus heat transfer means, located between an edge of the die substrate and a first heat source of the multiple heat sources; and
a second surplus heat transfer means located between the first heat source and a second heat source that is adjacent to the first heat source.

25. The heat spreader apparatus of claim 24, wherein the first surplus heat transfer means has a height that is not equal to a height of the second surplus heat transfer means.
